(19) United States
(12) Patent Application Publication
(10) Pub. No.: US 2021/0066113 A1
(43) Pub. Date: Mar. 4, 2021

(54) SUSCEPTOR, CVD APPARATUS, AND METHOD FOR MANUFACTURING EPITAXIAL WAFER

(71) Applicant: SHOWA DENKO K.K., Tokyo (JP)

(72) Inventors: Yoshikazu UMETA, Chichibu-shi (JP); Keisuke FUKADA, Chichibu-shi (JP); Naoto ISHIBASHI, Chichibu-shi (JP); Hironori ATSUMI, Chichibu-shi (JP)

(73) Assignee: SHOWA DENKO K.K., Tokyo (JP)

(21) Appl. No.: 16/644,250

(22) PCT Filed: Jun. 22, 2018
(86) PCT No.: PCT/JP2018/023891

§ 371 Date: Mar. 4, 2020

(30) Foreign Application Priority Data
Sep. 7, 2017 (JP) 2017-172012

(51) Int. Cl. H01L 21/687; H01L 21/02; C23C 16/458; C23C 16/32

(52) U.S. Cl. CPC H01L 21/6875; H01L 21/02167; H01L 21/68735; C23C 16/4585; C23C 16/325; H01L 21/02271

(57) ABSTRACT

A susceptor (1) of the present invention is a susceptor that is configured to hold a wafer in a CVD apparatus that forms a layer on a wafer through chemical vapor deposition, and includes an external susceptor (2) and an internal susceptor (1). The external susceptor (2) has an opening (2c) that accommodates the internal susceptor (1) in a coupling manner and has a wafer placement surface (2a) on which an outer peripheral portion (Ws) of a wafer is placed. The internal susceptor (1) includes a projection portion (1a) on a surface (1b) facing the wafer (W), and a height (h) of the projection portion (1a) is a height at which the projection portion does not come into contact with the wafer (W) when the wafer (W) is placed on the susceptor.

### TECHNICAL FIELD

The present invention relates to a susceptor, a CVD apparatus, and a method of manufacturing an epitaxial wafer. The application is based on Japanese Patent Application No. 2017-172012 filed on Sep. 7, 2017, the content of which is incorporated herein by reference.

### BACKGROUND ART

Silicon carbide (SiC) has characteristics such as a dielectric breakdown electric field being one order of magnitude larger, a band gap being three times larger, and a thermal conductivity being approximately three times higher than those of silicon (Si). Since silicon carbide has such characteristics, silicon carbide is expected to be applied to power devices, high frequency devices, high temperature operation devices and the like. For this reason, in recent years, SiC epitaxial wafers have been used in the above-described semiconductor devices.

An SiC epitaxial wafer is manufactured by growing an SiC epitaxial layer serving as an active region of an SiC semiconductor device on an SiC substrate (SiC wafer). An SiC wafer is obtained by being processed from a bulk single crystal of SiC manufactured by a sublimation method or the like, and an SiC epitaxial layer is formed by a chemical vapor deposition (CVD) apparatus.

An example of such a CVD apparatus is a device including a susceptor rotating about a rotation axis (wafer supporting stand). A wafer placed on the susceptor is rotated, so that it is possible to make a gas supply state in an in-plane direction uniform and grow a uniform epitaxial layer on an SiC substrate. The wafer is transported into the CVD apparatus using a manual or automatic transport mechanism and is placed on the susceptor. The susceptor on which the wafer is placed is heated from the back surface thereof, and a reaction gas is supplied to the front surface of the wafer from above, thereby forming an epitaxial layer.

A susceptor having a structure in which an inner susceptor and an outer susceptor are separated from each other is known (see, for example, Patent Document 1).

A susceptor disclosed in Patent Document 1 will be described with reference to FIGS. 6A to 6C. In this document, a susceptor 100 including an inner susceptor 101 and an outer susceptor 102 is disclosed. The diameter of the inner susceptor 101 is smaller than the diameter of a wafer W and includes a convex portion 101a for placing a wafer on the front surface thereof. The outer susceptor 102 has an opening 102c in the central portion thereof and is configured such that the opening 102c is blocked by the inner susceptor 101 placed thereon.

The outer susceptor 102 includes a step portion 102a supporting the wafer W and a step portion 102b supporting the inner susceptor 101. In addition, the inner susceptor 101 is configured such that the convex portions 101a having dot shapes and provided on the front surface 101b are disposed at substantially equal intervals around the same circumferential shape. The inner susceptor 101 supports the wafer W during the transport of the wafer W to the CVD apparatus. The inner susceptor is fitted to the opening 102c of the outer susceptor 102 during the growth thereof to also perform a role of preventing impurity gases from flowing in from a lower portion of a furnace.

In addition, the wafer W is supported by the step portion 102a of the outer susceptor 102 and the convex portions 101a of the inner susceptor 101 (Paragraph 0022 and the like of Patent Document 1), and an SiC epitaxial layer is formed in a state where a back surface Wa of the wafer W and the convex portions 101a of the inner susceptor 101 are in contact with each other. As shown in FIG. 6A, a gap S with a height equal to the height of the convex portion is formed between the back surface Wa of the wafer W and an upper surface 101b of the inner susceptor 101 other than the convex portions.

### CITATION LIST

### Patent Literature

Patent Document 1

Japanese Unexamined Patent Application, First Publication No. 2009-70915

### SUMMARY OF INVENTION

### Technical Problem

It is important to reduce a processing time of a wafer in order to improve an operation rate of a layer forming apparatus (CVD apparatus). Since a processing temperature of the CVD apparatus is high, most of the processing time is consumed during the heating and cooling time of a furnace. For this reason, shortening the heating and cooling time of the furnace is an important problem in reducing a processing time. When a wafer can be transported in and out of the furnace while the internal temperature of the furnace is high, a heating and cooling time of the furnace can be reduced, thereby improving an operation rate of a layer forming apparatus.

However, when a wafer near room temperature before processing is put into a high-temperature furnace when transporting the wafers into the furnace (high-temperature carrying-in) while the internal temperature of the furnace is high, a temperature distribution on a wafer surface becomes non-uniform due to a difference in these temperatures. For this reason, problems such as a crack due to strong thermal stress caused by temperature non-uniformity on the wafer surface, deviation of a positional relationship between the susceptor and the wafer caused by warpage of the wafer, or scattering of the susceptor, may occur when transporting the wafer.

In addition, a similar problem also occurs when a wafer in a high temperature state after processing is taken out of the furnace near room temperature.

Further, when a convex portion of an inner susceptor is in contact with the wafer during growth (see FIG. 6A) in a case where a high temperature of 1550° C. or higher is used as a growth temperature like in epitaxial growth of SiC, it has been found that surface roughness (back surface roughness) due to thermal deterioration of a wafer may occur in a portion in contact with a convex portion on the back surface of an epitaxial wafer.

An object of the present invention is to transport a wafer without causing roughness of the back surface of the wafer during epitaxial growth while maintaining a state where the wafer is stably placed on a susceptor even when the wafer is warped in a case where the wafer is transported to a furnace in a high temperature state.

### Solution to Problem

The inventors have found that when a warped wafer is transported in a state of being supported by a projection when high temperature transport is performed, the wafer can be stably placed on a susceptor and transported, and have found that it is possible to prevent the occurrence of roughness of a wafer back surface by limiting the height of the projection. That is, in order to solve the above-described problem, the present invention provides means such as a susceptor, an apparatus, and a method to be described below.

The present invention can provide a susceptor that holds a wafer in a CVD apparatus that forms a layer on the wafer through chemical vapor deposition, the susceptor including an external susceptor and an internal susceptor, in which the external susceptor has an opening that accommodates the internal susceptor in a coupling manner and has a wafer placement surface on which an outer peripheral portion of a wafer is placed, the internal susceptor includes a projection portion on a surface facing the wafer, and a height of the projection portion is a height at which the projection portion does not come into contact with the wafer when the wafer is placed on the susceptor.

That is, a first aspect of the present invention provides the following susceptor according to (1).

(1) A susceptor including an external susceptor and an internal susceptor, in which the external susceptor has an opening that accommodates the internal susceptor in a coupling manner and a wafer placement surface on which an outer peripheral portion of a wafer is placed, the internal susceptor includes at least one projection portion on a surface facing the wafer when the wafer is placed on the susceptor, and has a height of the projection portions is a height at which the projection portions do not come into contact with the wafer when the wafer is placed on the susceptor.

(2) The susceptor according to (1), in which the opening of the external susceptor is surrounded by a step, and the internal susceptor is fitted into the step to block the opening of the opening.

(3) The susceptor according to (1) or (2), in which the outer diameter of the internal susceptor is smaller than the outer diameter of the wafer to be placed thereon.

(4) The susceptor according to (1) to (3), in which the internal susceptor includes a plurality of projection portions, and the projection portions are disposed along the circumference of the circle or rotationally symmetrically around a circumference of or rotationally symmetrically on an upper surface of the internal susceptor.

(5) A CVD apparatus including a furnace which accommodates a wafer and forms a layer on the wafer through chemical vapor deposition, the susceptor according to any one of (1) to (4), and a vertical driving mechanism for raising and lowering the susceptor.

(6) A method of manufacturing an epitaxial wafer in which an SiC single crystal epitaxial layer is formed on an SiC single crystal wafer using the CVD apparatus according to (5), the method including a wafer transfer step of placing the wafer on an upper surface of the susceptor using the vertical driving mechanism, in which the wafer transfer step is performed at a high temperature of 800° C. or higher.

(7) The susceptor according to any one of (1) to (4), in which the susceptor is constituted by only the external susceptor and the internal susceptor.

(8) The susceptor according to (1), in which the susceptor is a susceptor that is configured to hold the wafer in a CVD apparatus that forms a layer on the wafer through chemical vapor deposition.

### Advantageous Effects of Invention

A susceptor of the present invention is a susceptor having a separated structure and is provided with minute circumferential projections on a wafer supporting surface of an internal susceptor supporting a wafer during transport to prevent the wafer from sliding down even when the wafer is warped. Thereby, it is possible to stably perform automatic transport of the wafer warped to downward convex shape in a high temperature state.

### BRIEF DESCRIPTION OF DRAWINGS

FIG. 1A is a schematic cross-sectional view showing an example of a susceptor of the present invention in a state where a wafer W is placed on the susceptor.

FIG. 1B is a schematic cross-sectional view showing an example of an external susceptor.

FIG. 1C is a schematic cross-sectional view showing an example of an internal susceptor.

FIG. 2A is a schematic plan view showing an example of a configuration in which a continuous annular projection portion is provided in an internal susceptor with respect to the center.

FIG. 2B is a schematic plan view showing an example of a configuration in which projection portions are disposed rotationally and symmetrically with respect to the center and spaced from each other in the internal susceptor.

FIG. 3 is a schematic cross-sectional view showing an outline of a CVD apparatus according to an embodiment of the present invention.

FIG. 4 is a schematic view showing a step of transporting a wafer into a furnace using the CVD apparatus shown in FIG. 3.

FIG. 5A is a schematic view showing a step of placing a wafer on a susceptor inside a furnace using the CVD apparatus shown in FIG. 3.

FIG. 5B is a schematic enlarged view of a location indicated by Vb in FIG. 5A.

FIG. 6A is a schematic cross-sectional view of a susceptor of a separated structure type of the conventional art in a state where a wafer W is placed on the susceptor.

FIG. 6B is a schematic cross-sectional view of an external susceptor of the separated structure type of the conventional art.

FIG. 6C is a schematic cross-sectional view of an internal susceptor of the separated structure type of the conventional art.

### DESCRIPTION OF EMBODIMENTS

Hereinafter, the present embodiment will be described in detail with reference to the accompanying drawings as appropriate. In the drawings used in the following description, characteristic portions may be illustrated at an enlarged scale for convenience of easy understanding of characteristics of the present invention, and the dimensional ratios and the like of the respective components may be the same as or different from the actual ones. Materials, dimensions, and the like provided in the following description are merely exemplary examples, and the present invention is not limited thereto and can be appropriately modified within a range in which the effects are exhibited. For example, addition, omission, replacement, and other changes can be made to members, numbers, positions, amounts, and the like without departing from the scope of the present invention.

(Susceptor)

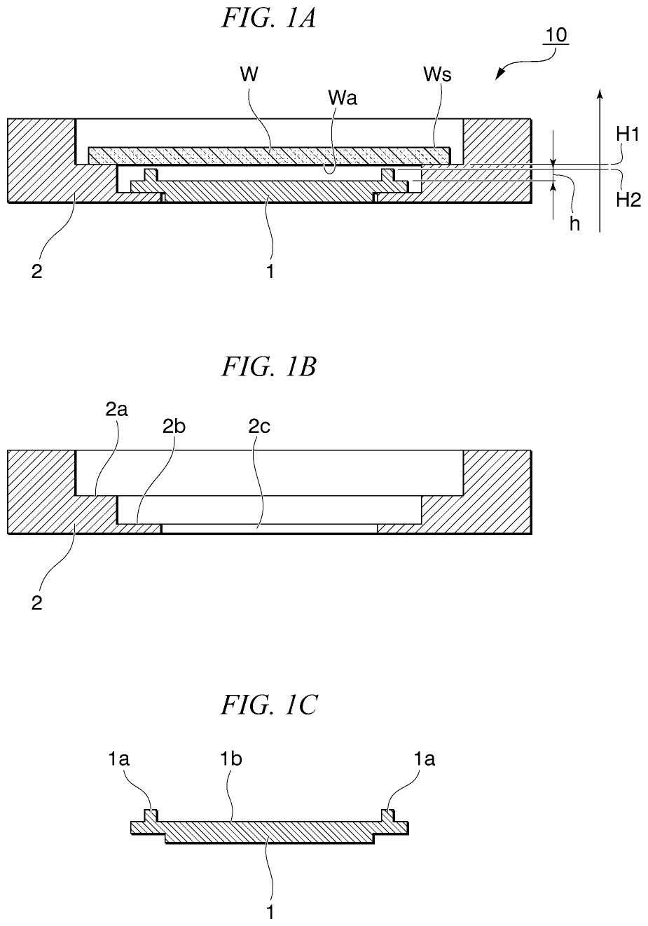

FIGS. 1A to 1C are schematic cross-sectional views showing an example of a susceptor according to an embodiment of the present invention. FIG. 1A is a schematic cross-sectional view of the susceptor in a state where a wafer W is placed on the susceptor, FIG. 1B is a schematic cross-sectional view of an external susceptor, and FIG. 1C is a schematic cross-sectional view of an internal susceptor.

A susceptor 10 shown in FIG. 1A is a susceptor that holds a wafer in a CVD apparatus that forms a layer on a wafer through chemical vapor deposition and includes an external susceptor 2 and an internal susceptor 1. The external susceptor 2 has an opening 2c that accommodates the internal susceptor 1 fitted thereto and has a wafer placement surface 2a on which an outer peripheral portion Ws of the wafer is placed. The internal susceptor 1 includes a projection portion 1a on a surface 1b facing the wafer W. A height h of the projection portion 1a is a height at which the projection portion 1a does not come into contact with the wafer W when the wafer W is placed on the susceptor (a state where the external susceptor and the internal susceptor are combined with each other). In other words, a position H2 of the height of the projection portion 1a is lower than a position H1 of the height of the wafer placement surface 2a. Further, in other words, the height of the projection portion 1a is smaller than a distance between the upper surface of the internal susceptor 1 and the lower surface of the wafer W. That is, the height of the projection portion 1a is smaller than the height of the side surface of a second stepped portion of the susceptor 10.

The susceptor of the present invention includes the internal susceptor 1 having an outer diameter smaller than the outer diameter of the wafer and the external susceptor 2 which is separable from the internal susceptor 1 as shown in FIG. 1A. The external susceptor has the opening 2c to which the internal susceptor is fitted. The internal susceptor is movable up and down by a vertical driving mechanism (push-up mechanism) to be described later. The external susceptor and the internal susceptor having the wafer placed thereon can be separated from each other by the internal susceptor being pushed up.

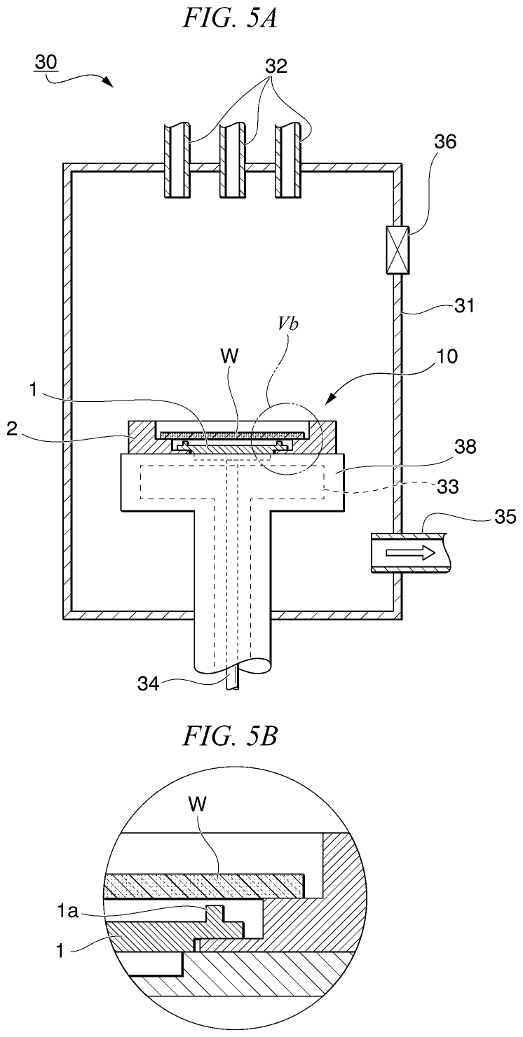

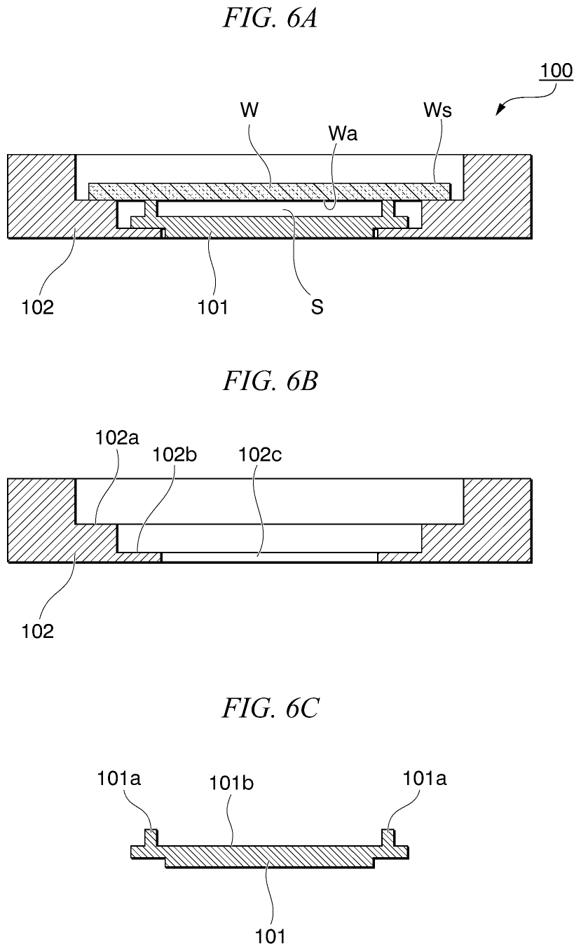

In a case where the susceptor of the present invention is used, the susceptor has a structure in which the wafer W does not come into contact with the internal susceptor during epitaxial growth, and the wafer placement surface 2a of the external susceptor 2 supports the wafer in contact with the lower surface of the outer peripheral portion Ws of the wafer (see FIG. 5B). The external susceptor 2 has the opening 2c in the center thereof and supports the wafer in a state where the internal susceptor is fitted into the opening by a step 2b provided in the vicinity of the opening. The internal susceptor 1 is fitted to the external susceptor 2 to block the opening 2c. The external susceptor 2 includes first, second, and third stepped portions from the top when seen in a cross-sectional view. The wafer W is preferably accommodated in an accommodation portion inside of the side surface of the first stepped portion and is disposed on a first surface (wafer placement surface) of the second stepped portion. The internal susceptor 1 is preferably accommodated in an accommodation portion inside of the side surface of the second stepped portion of the external susceptor 2 and on the side inward from an opening provided by the third stepped portion (step 2b). The opening 2c may be conceived as an opening portion in which an opening is provided in the front surface (upper surface) of the third stepped portion. Each of the first to third stepped portions is preferably constituted by a first surface (upper surface) and a second surface (side surface: a surface which is continuous with and perpendicular to the upper surface). Alternatively, the surface continuous with the upper surface may not be perpendicular to the upper surface as long as it can play this role. Preferably, the upper surface is flat. When the external susceptor is seen from above, it is also preferable that the side surfaces of the first, second, and third stepped portions be disposed concentrically.

The internal susceptor 1 having the wafer placed thereon includes the projection portion 1a so as to be capable of supporting the wafer in a high temperature state (downward convex warped state) without slipping when the internal susceptor is moved by a push-up mechanism or the like. When the wafer is transported, the projection portion 1a of the internal susceptor 1 supports the wafer in contact with the lower surface of the wafer W.

In a case where transport is performed at a high temperature, the wafer may be warped in a downward convex shape due to the influence of heat, that is, so as to be bent downward. When the projections are not provided, the wafer in a downward convex warped state and the front surface of the internal susceptor come into contact with each other only at points, and a contact area is reduced. For this reason, the wafer easily slides down during transport. In this manner, in a case where the wafer is warped in a downward convex shape, the wafer cannot be stably held when the upper surface of the internal susceptor is flat or convex. For this reason, it is preferable to have a plurality of projection portions which are minute convex structures disposed along the circumference of the circle or rotationally and symmetrically in an outer peripheral portion of a flat plate on the upper surface of the internal susceptor.

On the other hand, when the projection portions are in contact with the back surface of the wafer during epitaxial growth, back surface roughness occurs at these contact portions. When back surface roughness occurs, these portions become cloudy, and thus a failure may occur in operations after epitaxial growth. For this reason, it is desirable for the size of any back surface roughness to be as small as possible. Even when the projection portions do not come into contact with the back surface of the wafer, the size of any back surface roughness becomes larger as a distance between the back surface of the wafer and the susceptor decreases. For this reason, when a projection in the front surface of the susceptor is excessively large, a distance between the wafer and the susceptor is reduced, and thus the size of any back surface roughness becomes larger. For this reason, it is desirable that the projection in the front surface of the susceptor be made small within a range in which the warpage of the wafer can be sufficiently absorbed. When the distance between the back surface of the wafer and the front surface of the internal susceptor is reduced, the uniformity of epitaxial characteristics such as a layer thickness and a doping concentration also deteriorate, and thus it is desirable that the warpage of the wafer be reduced to a range in which the warpage can be sufficiently absorbed in view of characteristics of an epitaxial growth layer.

For this reason, as a compatible range, a distance between the back surface of the wafer and the front surface of the susceptor is preferably 1.5 mm to 5.0 mm, and more preferably 1.8 mm to 3.2 mm. The height of the projection portion is set to be in a range in which the projection portion does not come into contact with the back surface of the wafer during epitaxial growth. The height is preferably 0.1 mm to 0.5 mm and more preferably 0.2 mm to 0.3 mm. In addition, a difference in height between the upper surface of the projection portion of the internal susceptor and a wafer placement surface of the external susceptor (wafer back surface) is preferably set to be 1.0 mm to 4.9 mm, and more preferably 1.5 mm to 3 mm in a state where the external susceptor and the internal susceptor are combined with each other (a state of being used as a susceptor).

When the internal susceptor and the external susceptor are combined with each other, the projection portion of the internal susceptor is higher than the height of the wafer placement surface (wafer supporting surface) of the external susceptor. The internal susceptor and the wafer are separated from each other during epitaxial growth, and a space is formed therebetween. Therefore, even when a support portion having a circumferential shape is not provided with a notch, lifting of the wafer due to gas accumulation during epitaxial growth can be curbed.

Characteristics of the epitaxial layer reflect a temperature distribution derived from the shape of the susceptor. In order to realize uniform characteristics in a circumferential direction, it is desirable that the shape of the susceptor be symmetric in the circumferential direction. For the same reason, it is desirable that a ring-shaped projection portion does not have a notch. When uniform characteristics are obtained in the circumferential direction, a characteristics inspection can be represented with inspection values by inspecting one line in a diameter direction, which is effective for improving the number of processes in the characteristics inspection.

As shown in FIG. 1A, in an example of a specific structure of the susceptor, the external susceptor has an annular shape when seen from above. Also, the external susceptor is coupled to the internal susceptor in a state where the internal susceptor is fitted to a stepped portion provided inside. The inside of the external susceptor is sealed by the internal susceptor in a coupled state. It is possible to prevent impurities from flowing in from a lower portion of a furnace due to the sealed external susceptor.

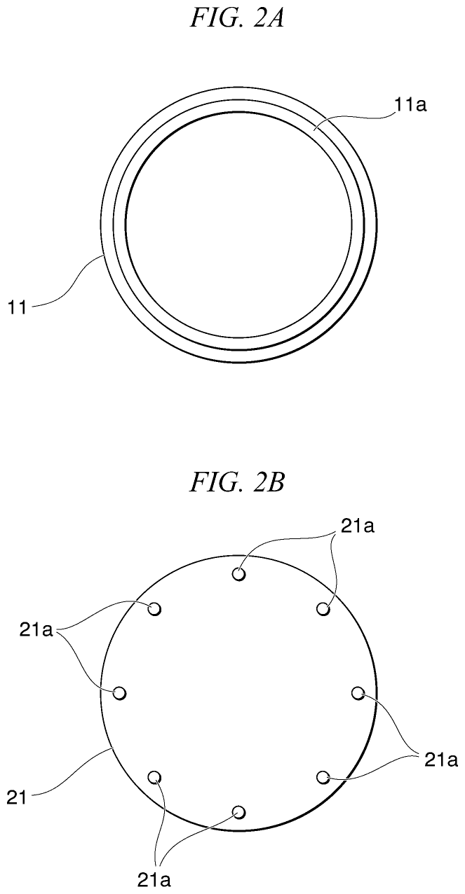

FIGS. 2A and 2B are schematic plan views showing an example of an internal susceptor according to an embodiment of the present invention.

An internal susceptor 11 shown in FIG. 2A includes a projection portion 11a on a surface facing a wafer W. The projection portion 11a has an annular configuration being continuous with respect to the center of the internal susceptor 11 and having no cut line. The projection portion is formed in a continuous annular shape having no cut line to come into line contact with the lower surface of the wafer along a downward convex, and thus the wafer can be stably supported.

An internal susceptor 21 shown in FIG. 2B includes a plurality of (eight) projection portions 21a on a surface facing the wafer W. The eight projection portions 21a are configured to be disposed rotationally and symmetrically with respect to the center and spaced from each other in the internal susceptor 11. The plurality of projections are provided, and thus it is possible to reduce the area of the projections and reduce the influence of back surface roughness of the wafer caused by the projections.

Although a material of the susceptor can be arbitrarily selected, it is preferable to use a susceptor made of a solid base material which withstands high temperature, such as graphite, SiC, Ta, Mo, or W, or a material subjected to carbonized metal coating such as SiC coating or TaC coating.

The internal susceptor is provided with, for example, a ring-shaped projection having a radius of 80% of the radius of the outer shape of the internal susceptor. The height of the projection portion is, for example, 0.2 mm. Since a contact length between the internal susceptor and the wafer increases as the position of the projection becomes closer to an outer circumference side, transport becomes stable. However, in order to absorb the height of a downward convex of the wafer, the height of the projection portion needs to become larger than the height of the downward convex, thereby increasing the size of any back surface roughness. Since a contact length between the internal susceptor and the wafer decreases as the position of the projection becomes closer to an inner circumference side, transport becomes unstable. However, it is possible to reduce the height of the projection portion for absorbing the downward convex of the wafer, thereby reducing the size of any back surface roughness. Therefore, it is desirable that the projection be positioned on the inner side within a range in which stable transport can be performed. A distance between the center of the internal susceptor and the projection having a ring shape can be set to be a position of 40% to 90% of the radius of the wafer. The outer diameter of the internal susceptor may be determined in consideration of the position of the projection portion. In a state where the internal susceptor is placed on the external susceptor, a difference between a surface except for the projection portion of the internal susceptor and the height of a wafer placement surface of the external susceptor is, for example, 2 mm. Therefore, in a case where the wafer is installed in a state where the susceptor is coupled, the lower surface of the wafer does not come into contact with the projection portion.

(CVD Apparatus)

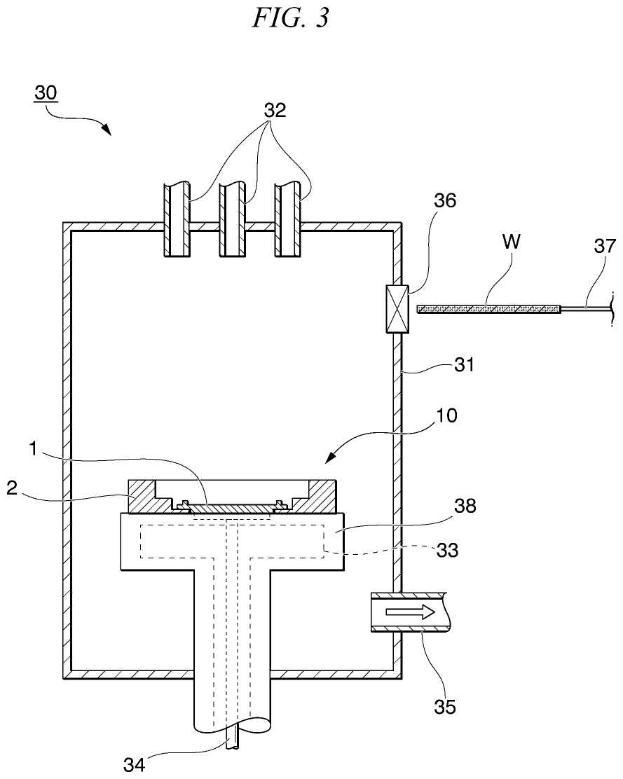

FIG. 3 is a schematic cross-sectional view showing an outline of a CVD apparatus according to an embodiment of the present invention. A CVD apparatus 30 shown in FIG. 3 includes a furnace 31 that accommodates a wafer and forms a layer on the wafer through chemical vapor deposition, a gas supply mechanism 32 for supplying a processing gas to the furnace 31, a susceptor 10 of the present disclosure, a heater 33 for heating the wafer from below the susceptor 10, a rotation mechanism 38 for rotating the wafer, and a vertical driving mechanism 34 that passes through the heater and raises and lowers the internal susceptor 1. In an example shown in FIG. 3 to FIG. 5B, only the internal susceptor 1 is raised and lowered by the vertical driving mechanism 34, but a vertical driving mechanism configured to raise and lower the entire susceptor 10 may be used.

The CVD apparatus 30 shown in FIG. 3 further includes a gas discharge portion 35 for discharging a processing gas from the furnace and a gate valve 36 serving as an opening portion for transporting the wafer into the furnace, and includes a transport mechanism 37 that transports the wafer into the furnace through the gate valve 36.

FIG. 3 to FIG. 5B show an example of a step of transporting a wafer into a furnace and placing the wafer on a susceptor in a stepwise manner.

Referring to FIG. 3, first, a wafer W is placed on the transport mechanism 37 on the outer side of a furnace. The transport mechanism 37 includes, for example, a U-shaped transport hand for supporting an outer peripheral portion of the wafer W to be capable of moving the wafer in a horizontal direction. The U-shaped transport hand is configured to have, for example, a width larger than the outer diameter of an internal susceptor and smaller than that of the wafer, so that the U-shaped transport hand can be formed to have a shape for replacing the wafer on the internal susceptor or removing the wafer from the internal susceptor without coming into contact with the internal susceptor.

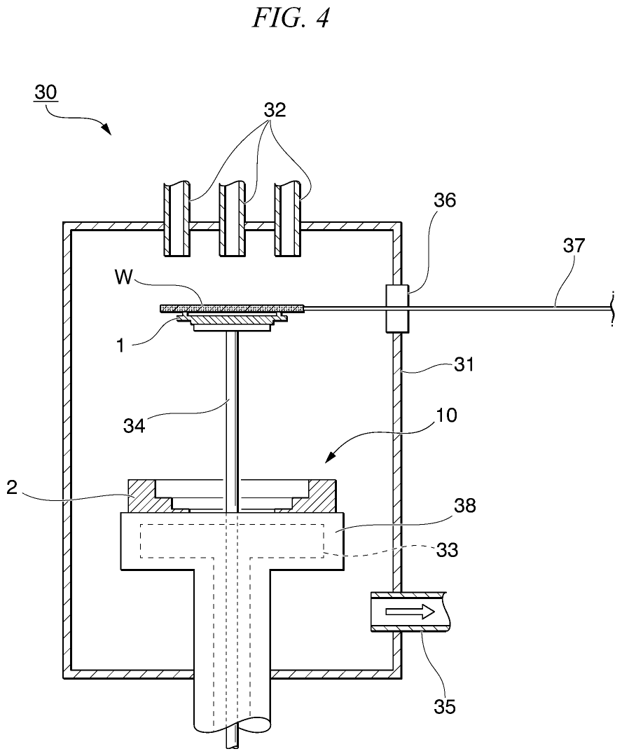

Next, referring to FIG. 4, the internal susceptor 1 is raised by the vertical driving mechanism 34. The vertical driving mechanism 34 is an arbitrary structure which is configured to support the internal susceptor so as to be able to move up and down while keeping the internal susceptor horizontal. For example, an upper end of the vertical driving mechanism may have a horizontal plate shape or a rod shape, and may have a structure in which push-up pins are disposed at a plurality of locations, for example, at three locations in the upper portion thereof and the push-up pins support and lift the internal susceptor. It is preferable that the upper end of the vertical driving mechanism have a small shape within a range in which the susceptor can be supported. The wafer W can be placed on the internal susceptor while the internal susceptor is pushed up by the vertical driving mechanism 34 during transport. The outer diameter of the internal susceptor is smaller than the outer diameter of the wafer.

In a state where the internal susceptor 1 is raised by the vertical driving mechanism 34, the gate valve 36 of the furnace is opened, and the wafer W placed on the transport hand of the transport mechanism 37 is transported into the furnace 31 from the opening portion. When the wafer W is positioned just above the internal susceptor 1, the internal susceptor 1 is raised by the vertical driving mechanism 34 to place the wafer W on the internal susceptor 1.

The wafer W is transported by the transport hand to a position where the internal susceptor 1 is placed. A wafer support portion of the transport hand has a gap which is larger than the outer diameter of the internal susceptor but smaller than the outer diameter of the wafer W between two hands of the U-shaped transport hand. The internal susceptor 1 and the wafer W can be separated from each other by moving the hand below the internal susceptor 1.

After the wafer W is placed on the internal susceptor 1, the transport hand is moved to the outside of the furnace 31, and the gate valve 36 is closed.

Thereafter, the internal susceptor 1 having the wafer W placed thereon is lowered by the vertical driving mechanism 34 and is fitted to the opening of the external susceptor 2 (see FIG. 5A). In this case, it is desirable that the upper end of the vertical driving mechanism be separated from the lower surface of the susceptor. When the upper end is in contact with the susceptor, heat escapes from the susceptor through the vertical driving mechanism when the temperature rises, which leads to an undesirable result.

In this state, the wafer W is heated by applying current to the heater 33, and a material gas such as silane which is a silicon source, propane which is a carbon source, hydrogen which is a carrier gas, and nitrogen as a dopant is made to flow from the gas supply portion 32 to perform SiC epitaxial growth.

As the above-described transport of the wafer into the furnace, high temperature transport which is performed in a state where the inside of the furnace heated by the heater 33 is set to be at a high temperature can be performed.

In the above description, an example in which only an internal susceptor is raised separately from a rotation mechanism by being driven up and down in a step of transporting a wafer and placing the wafer on a susceptor has been described. However, a configuration in which a susceptor in a state where an internal susceptor is fitted to an external susceptor is raised separately from a rotation mechanism by a vertical driving mechanism and is transported inside and outside a furnace may be adopted. In this case, a location where the susceptor in a state where the internal susceptor is fitted to the external susceptor is separated or coupled may be provided inside or outside the furnace, so that the external susceptor and the internal susceptor can be separated from or coupled to each other at the location. The susceptor that has been just removed from the furnace is at a high temperature even when the external susceptor and the internal susceptor are separated from or coupled to each other outside the furnace. For this reason, a problem due to high temperature transport which is similar to that in transport performed inside the furnace may occur, and thus the present disclosure is effective.

(Method of Manufacturing Epitaxial Wafer)

The wafer W is placed on the susceptor 10 in a state where the internal susceptor 1 is fitted to the external susceptor 2 positioned on the rotation mechanism 38 using the CVD apparatus shown in FIG. 3 to FIG. 5B and using the transport mechanism 37 and the vertical driving mechanism 34 (see FIG. 5). In this case, the inside of the furnace is maintained at 800° C. or higher by applying current to the heater 33. In addition, the wafer W is also maintained at 800° C. or higher in a state where the wafer is placed on the transport hand of the transport mechanism 37 outside the furnace 31. In order to maintain the wafer at a high temperature outside the furnace 31, a heating region where a heater is installed may be provided outside the furnace. At the time of high temperature transport, a gas that does not contribute to crystal growth, for example, argon, hydrogen, or the like can be made to flow. Alternatively, transport can be performed under vacuum.

Thereafter, the wafer is heated to an epitaxial growth temperature of 1550° C. by making hydrogen flow into the furnace, maintaining pressure at a predetermined pressure, and then increasing a current of the heater. After the temperature reaches a temperature at which an SiC epitaxial layer grows, a silicon material gas, for example, a material gas containing silicon and a carbon material gas, for example, propane is made to flow from a gas supply mechanism to grow an SiC epitaxial layer on an SiC substrate. After the growth is terminated, the flowing of the material gas is stopped, the output of the heater is reduced, and the temperature is lowered to 800° C. After the temperature reaches 800° C., the wafer is taken out of the furnace using the transport mechanism 37 and the vertical driving mechanism 34. Transport is performed at a high temperature of 800° C. or higher, and thus the wafer can be stably transported even when the wafer is warped.

In the above description, a case where a CVD apparatus that drives only an internal susceptor up and down to raise the internal susceptor separately from a rotation mechanism in a step of transporting a wafer and placing the wafer on a susceptor and combines the internal susceptor and an external susceptor with each other in the furnace is used has been described. Meanwhile, in a case where a location where the separation and coupling of the susceptor are performed is provided inside or outside the furnace and the wafer is placed on the susceptor outside the furnace, a configuration in which the wafer is taken out of the furnace, placed on the susceptor within five minutes, transported, and set in the CVD apparatus can also be preferably used.

### INDUSTRIAL APPLICABILITY

There is provided a susceptor that does not cause roughness of a back surface of a wafer during epitaxial growth while maintaining a state where the wafer is stably placed on the susceptor even the wafer is warped in a case where the wafer is transported in a furnace in a high temperature state.

### REFERENCE SIGNS LIST

1, 11, 21 Internal susceptor
1a, 11a, 21a Projection portion
1b Surface facing wafer
2 External susceptor
2a Wafer placement surface
2b Step
2c Opening
10 Susceptor
30 CVD apparatus
31 Furnace
32 Gas supply portion
33 Heater
34 Vertical driving mechanism
35 Gas discharge portion
36 Gate valve
37 Transport mechanism
38 Rotation mechanism that rotates wafer
100 Susceptor
101 Inner susceptor
101a Convex portion of inner susceptor
101b Upper portion of inner susceptor
102 Outer susceptor
102a Step portion that supports wafer
102b Step portion that supports inner susceptor
102c Opening
W wafer
Wa Back surface of wafer
Ws Outer peripheral portion of wafer
h Height of projection portion 1a
H1 Position of the height of the wafer placement surface 2a
H2 Position of height of projection portion 1a
Vb Range of FIG. 5B which is enlarged from FIG. 5A
S Gap between back surface of wafer and upper surface of inner susceptor other than convex portion

1.-8. (canceled)

9. A susceptor comprising:
an external susceptor;
and an internal susceptor,
wherein the external susceptor has an opening that accommodates the internal susceptor in a coupling manner and has a wafer placement surface on which an outer peripheral portion of a wafer is placed,
the internal susceptor includes at least one projection portion on a surface facing the wafer when the wafer is placed on the susceptor, and
a height of the projection portion is a height at which the projection portion does not come into contact with the wafer when the wafer is placed on the susceptor.

10. The susceptor according to claim 9, wherein the opening of the external susceptor is surrounded by a step, and the internal susceptor is fitted into the step to block the opening.

11. The susceptor according to claim 9, wherein the outer diameter of the internal susceptor is smaller than the outer diameter of the wafer to be placed thereon.

12. The susceptor according to claim 9, wherein the internal susceptor includes a plurality of projection portions, and the projection portions are disposed along the circumference of the circle or rotationally symmetrically around a circumference of or rotationally symmetrically on an upper surface of the internal susceptor.

13. A CVD apparatus comprising:
a furnace which accommodates a wafer and forms a layer on the wafer through chemical vapor deposition;
the susceptor according to claim 9; and
a vertical driving mechanism configured to raise and lower the susceptor.

14. A method of manufacturing an epitaxial wafer in which an SiC single crystal epitaxial layer is formed on an SiC single crystal wafer using the CVD apparatus according to claim 13, the method comprising:
a wafer transfer step of placing the SiC single crystal wafer on an upper surface of the susceptor using the vertical driving mechanism,
wherein the wafer transfer step is performed at a high temperature of 800° C. or higher.

15. The susceptor according to claim 9, wherein the susceptor is constituted by only the external susceptor and the internal susceptor.

16. The susceptor according to claim 9, wherein the susceptor is a susceptor that is configured to hold the wafer in a CVD apparatus that forms a layer on the wafer through chemical vapor deposition.

17. The susceptor according to claim 9, wherein a height of the projection portion is 0.1 mm to 0.5 mm.

18. The susceptor according to claim 9, wherein a difference in height between an upper surface of the projection portion of the internal susceptor and the wafer placement surface of the external susceptor is 1.0 to 4.9 mm.

19. The susceptor according to claim 9, wherein the projection portion has an annular configuration being continuous with respect to the center of the internal susceptor, and the projection portion has no cut line.

20. The susceptor according to claim 9, wherein the projection portion does not have a notch.

21. The susceptor according to claim 9, wherein the internal susceptor includes a plurality of projection portions, and the projection portions are configured to be disposed rotationally and symmetrically with respect to the center and the spaced each other on an upper surface of the internal susceptor.

22. The method of manufacturing an epitaxial wafer according to claim 14, wherein a distance between the back surface of the SiC single crystal wafer and the front surface of the susceptor is 1.5 mm to 5.0 mm.

23. The method of manufacturing an epitaxial wafer according to claim 14, wherein a distance between the center of the internal susceptor and the projection is 40% to 90% of the SiC single crystal wafer.
